(19) United States
(12) Patent Application Publication
(10) Pub. No.: US 2017/0282720 A1
(43) Pub. Date: Oct. 5, 2017

(54) Power Converting Device

(71) Applicant: Hitachi, Ltd., Chiyoda-ku, Tokyo (JP)

(72) Inventors: Junichi SAKANO, Tokyo (JP); Kohhei ONDA, Tokyo (JP); Takeshi TAMAKOSHI, Tokyo (JP)

(21) Appl. No.: 15/511,910

(22) PCT Filed: Aug. 21, 2015
(86) PCT No.: PCT/JP2015/073451

§ 371 Date: Mar. 16, 2017

(30) Foreign Application Priority Data
Sep. 19, 2014 (JP) 2014-190673

(51) Int. Cl. B60L 3/00; G11C 7/10; B62M 6/65; H02M 7/48; B62M 6/55; G06F 9/30

(52) U.S. Cl. CPC B60L 3/0061; B62M 6/55; G06F 9/30; B62M 6/65; H02M 7/48; G11C 7/1006; B60K 2001/006

(57) ABSTRACT

By detecting a temperature abnormality of a power semiconductor by using the power semiconductor as a temperature sensor, it is possible to detect deterioration and an abnormality of elements, a drive circuit and a cooling system, prevent a failure during an operation by taking an appropriate measure in advance, and make a system operational life long. More specifically, a power converting device which includes the power semiconductor and an arithmetic operation circuit which gives a drive instruction to the power semiconductor detects the temperature abnormality of the power semiconductor based on the drive instruction of the power semiconductor and a delay time of a control drive voltage applied to the power semiconductor to protect the power converting device. The power converting device which includes the power semiconductor and the arithmetic operation circuit gives the drive instruction compares and determines a delay time of the drive instruction and a control voltage applied to the power semiconductor and a reference value, and changes at least one of the drive instruction and the drive voltage based on a result of the comparison and the determination.

### TECHNICAL FIELD

The present invention relates to a power converting device. More particularly, the present invention relates to a power converting device which is used for a large-volume frequency converting device for use to control electric motors for railway vehicles and large industries, and for power systems, and includes a power semiconductor switching element.

### BACKGROUND ART

Conventionally, as a technique of avoiding damages on a device when a power semiconductor abnormally operates, there is a technique of comparing a control drive instruction signal for a drive circuit which drives the power semiconductor, and operation information for detecting an operation state where the drive circuit drives the power semiconductor to conduct or interrupt, and determining the abnormal operation of the drive circuit when a mismatch continues for a certain period of time (see, for example, PTL 1).

Further, conventionally, as a technique of directly sensing a temperature abnormality of a semiconductor chip, there is a technique of detecting a control instruction signal and a delay time taken until the power semiconductor is interrupted, and thereby detecting a temperature rise of a power bipolar transistor (see, for example, PTL 2).

### CITATION LIST

### Patent Literature

PTL 1: JP 5049817 B2

PTL 2: JP 7-170724 A

### SUMMARY OF INVENTION

### Technical Problem

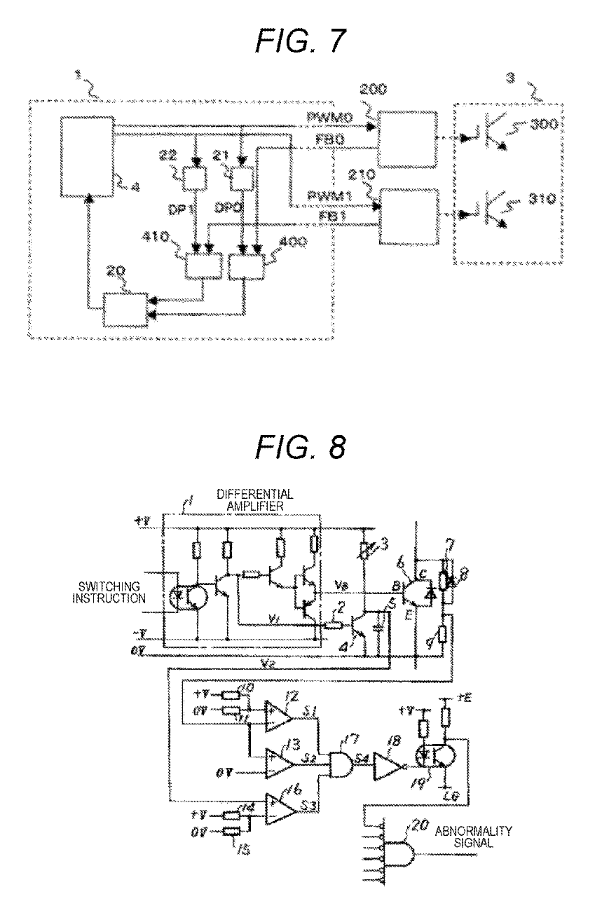

A power converter such as a large-volume frequency converter for use to control electric motors for railway vehicles and large industries and for power systems controls power of a high voltage and a large current. However, when an element failure occurs, a power supply short-circuits, and the power converter is likely to fall in a remarkable troubled state. It is necessary to stop a power converter as early as possible and avoid damages on the device when a power semiconductor abnormally operates to prevent such a situation. Hence, there is adopted an abnormality detecting method for comparing a control drive instruction signal for a drive circuit which drives the power semiconductor, and operation information for detecting an operation state where the drive circuit drives the power semiconductor to conduct or interrupt, and determining the abnormal operation of the drive circuit when a mismatch continues for a certain period of time. A conventional example of such a method is the technique disclosed in PTL 1, and FIG. 7 illustrates a configuration example of this method. When such a method is used, it is possible to determine an abnormal operation of the drive circuit. However, such a detecting method can detect an abnormality for the first time when a power supply of a power semiconductor is short-circuited, and therefore can prevent damages on the device yet has difficulty in continuing operating in this state due to a concern of a repeated occurrence of the abnormal operations. Further, when the power supply short-circuits due to a failure of the power semiconductor, an operation itself becomes impossible.

Hence, it is desirable to detect in advance an abnormality of a device which results in such power supply short-circuiting, and take an appropriate measure. Hence, there is a method for, for example, providing a temperature sensor near a power semiconductor and detecting an overtemperature abnormality of the power semiconductor. However, this method has difficulty in detecting a temperature rise of a semiconductor chip caused by a rise in a thermal resistance in the power semiconductor. Hence, it is demanded to directly detect a temperature abnormality of the semiconductor chip. A technique disclosed in PTL 2 is conventionally such a technical example. FIG. 8 illustrates a configuration example of the technique. In this example, by detecting a control instruction signal and a delay time taken until a power semiconductor is interrupted, a temperature rise of a power bipolar transistor is detected.

In this example, a circuit which determines an output voltage of the power semiconductor is necessary to detect an abnormal rise in a temperature of the power semiconductor. However, a large-volume power converting device controls a high voltage. Therefore, it is difficult to install a voltage divider of a large size, it is necessary to provide at least six power semiconductors when three-phase alternating currents are controlled and provide at least three voltage dividers to evaluate voltages of the power semiconductors, it is necessary to take a measure for significant noise during switching since a large current is handled, and therefore it is difficult to apply the large-voltage power converting device.

Hence, an object is to precisely detect an abnormality and deterioration of a power semiconductor and a power converting device related to the power semiconductor device and precisely prevent a trouble such as a failure while employing a simple configuration. Further, an object is to provide a method for enabling long-term use of the power semiconductor and the power converting device.

### Solution to Problem

To solve the above problem, a power converting device according to the present invention is, for example, a power converting device which includes a power semiconductor device; and an arithmetic operation circuit which gives a drive instruction to the power semiconductor, and the power converting device has a function of calculating for a drive instruction to conduct or interrupt the power semiconductor a delay time taken until an output voltage of a drive circuit applied to the power semiconductor in response to a change in the drive instruction reaches a determination value, and compares and determines the delay time and a reference value under a specific drive condition, records or displays and outputs a result of the determination, or changes at least one of the drive instruction and the drive voltage based on a result of the comparison and the determination.

### Advantageous Effects of Invention

According to the present invention, it is possible to provide a method which can precisely detect an abnormality or detection of a power semiconductor and a power converting device related to the power semiconductor and precisely prevent a trouble such as a failure while employing a simple configuration, and which enables long-term use of the power semiconductor and the power converting device.

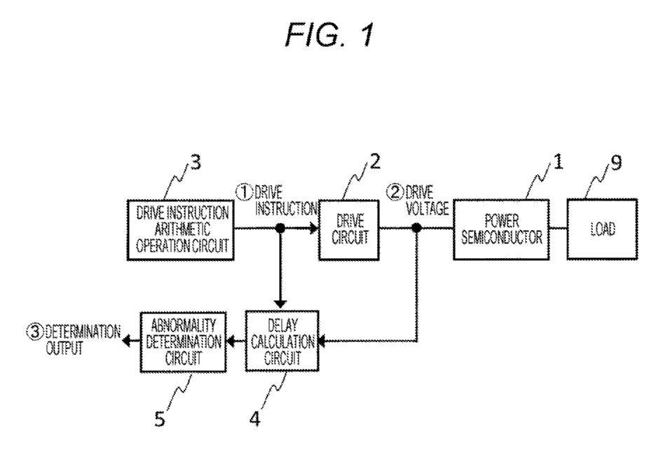

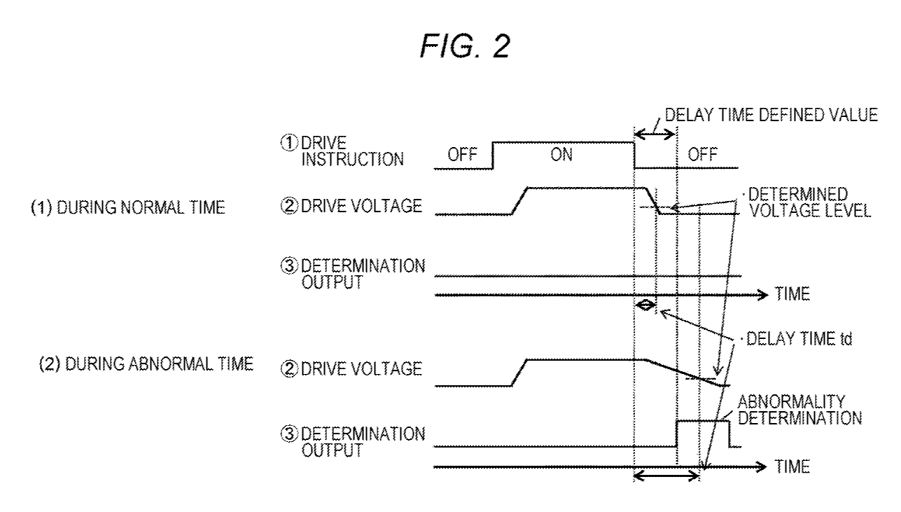

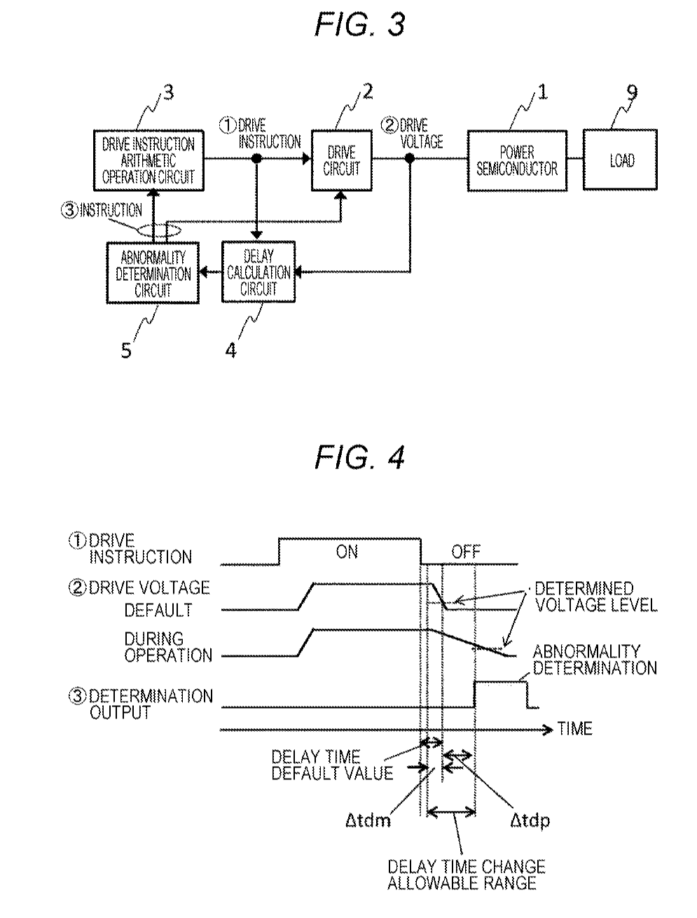

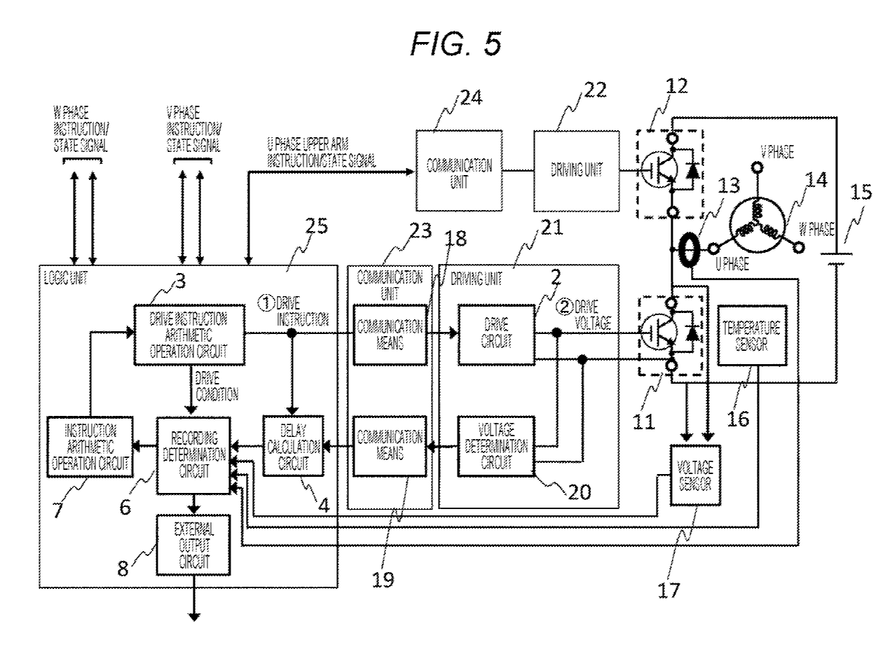

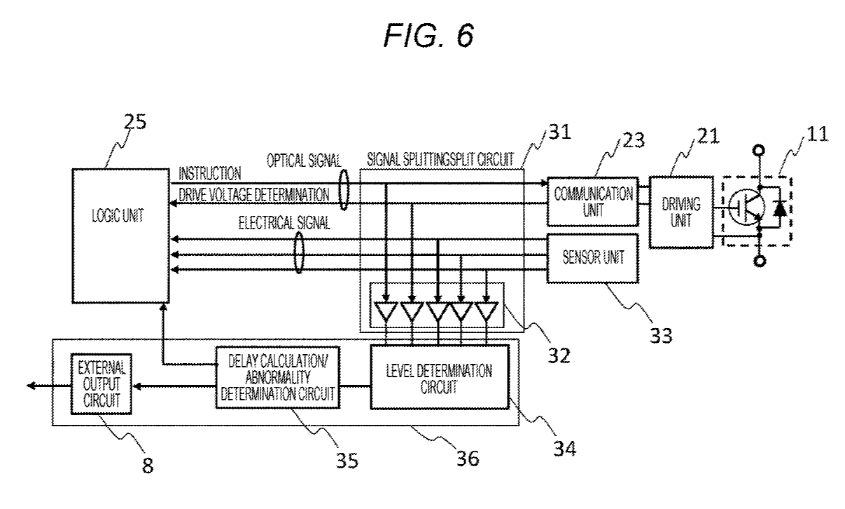

### BRIEF DESCRIPTION OF DRAWINGS

[FIG. 1] FIG. 1 is a view illustrating a block configuration of a power converting device according to Example 1 which is Embodiment 1 of the present invention.

[FIG. 2] FIG. 2 is a view illustrating a waveform of each signal of the power converting device according to Example 1 which is Embodiment 1 of the present invention.

[FIG. 3] FIG. 3 is a view illustrating a block configuration of a power converting device according to example 2 which is Embodiment 2 of the present invention.

[FIG. 4] FIG. 4 is a view illustrating a waveform of each signal of the power converting device according to example 2 which is Embodiment 2 of the present invention.

[FIG. 5] FIG. 5 is a view illustrating a block configuration of a power converting device according to example 3 which is Embodiment 3 of the present invention.

[FIG. 6] FIG. 6 is a view illustrating a block configuration of a power converting device according to example 4 which is Embodiment 4 of the present invention.

[FIG. 7] FIG. 7 is a view illustrating an example of a conventional power converting device.

[FIG. 8] FIG. 8 is a view illustrating another example of the conventional power converting device.

### DESCRIPTION OF EMBODIMENTS

A power converting device according to the present invention is a power converting device which includes a power semiconductor device; and an arithmetic operation circuit which gives a drive instruction to the power semiconductor, and the power converting device has a function of calculating for a drive instruction to conduct or interrupt the power semiconductor a delay time taken until an output voltage of a drive circuit applied to the power semiconductor in response to the drive instruction reaches a determination value, and compares and determines the delay time and a reference value under a specific drive condition, records or displays and outputs a result of the determination, or changes at least one of the drive instruction and the drive voltage based on a result of the comparison and the determination. For the power semiconductor, an insulation gate bipolar transistor, a power MOSFET or a MOS gate control power semiconductor element may be used. According to this configuration, the specific drive condition for making comparison and determination using the reference value maybe configured to be one of an output current value of the power converting device, a direction of an output current flowing in the power semiconductor, an inter-output terminal voltage of the power semiconductor, a power voltage and a temperature in the power converting device or may be configured to be a combination of the output current value, the direction, the inter-output terminal voltage, the power voltage and the temperature. Further, the delay time measured in advance by the power converting device may be recorded and a value calculated by performing an arithmetic operation on a value of the delay time may be used for the reference value used to make comparison with and determination on the delay time. Furthermore, when a result obtained by the comparison and the determination is recorded, and a number of times of the recording or a time interval of the recording satisfies a given condition, a display output or at least one of the drive instruction and the drive voltage may be configured to be changed. Still further, the drive instruction or the drive voltage may be configured to be changed to interrupt the power semiconductor for a certain period of time based on a result of the comparison and the determination. Moreover, a time width of a conduction instruction of the power semiconductor according to the drive instruction may be configured to be decreased based on a result of the comparison and the determination. Besides the power converting device may further include: means which communicates a signal of the drive instruction, and a signal of a result indicating that the output voltage of the drive circuit has reached the determination value between the arithmetic operation circuit and the power semiconductor; and a determination circuit which receives an input of the signal of the communication means and a signal related to the specific drive condition, and compares and determines the delay times and the reference value, and a result of the determination may be configured to be outputted to the arithmetic operation circuit or the drive circuit. Further, the power converting device may be configured to include communication means which records the result of the determination and outputs a result of the recording to an outside.

Embodiments of a power converting device according to the present invention will be described in detail below as each example with reference to drawings.

### Example 1

FIG. 1 illustrates a block configuration of a power converting device according to Example 1 which is Embodiment 1 of the present invention, and FIG. 2 illustrates examples of a drive signal, a control voltage and a determined output waveform. A drive circuit 2 in the power converting device according to the present invention in FIG. 1 converts a drive instruction generated by a drive instruction arithmetic operation circuit 3 into a drive voltage, and controls conduction and interruption of a power semiconductor 1 and thereby drives a load 9. A delay calculation circuit 4 calculates for the drive instruction a delay time taken until the drive voltage reaches a fixed determination value in response to a change in the drive instruction, and an abnormality determination circuit 5 compares a value of the delay time and a reference value, and outputs a comparison result. FIG. 2 illustrates a waveform according to an embodiment of the present invention when the power semiconductor is interrupted, i.e., is turned off. A drive voltage changes with a delay time td from the same drive instruction during a normal time. Characteristics of the power semiconductor change this delay time based on a condition. Our survey has confirmed that this delay time depends on a temperature of the power semiconductor. Power semiconductors generally have such temperature dependence. However, compared to an output voltage of a control circuit of a bipolar transistor equal to or less than 1 V, an output voltage of a control circuit of a MOS gate control element has a high amplitude of several V to several ±10 V, and a large margin with respect to noise caused during conduction and interruption of a power semiconductor is secured. Consequently, it is possible to enhance delay time evaluation precision.

For example, an insulation gate bipolar transistor which is a MOS gate control power semiconductor, i.e., an IGBT can measure and confirm an increase in a delay time of approximately 1 ns per 1° C. of a temperature rise in the power semiconductor by setting an appropriate state determination voltage during on/off switching at +15 V and −12 V of a voltage amplitude of a control circuit. This reflects a threshold of a control voltage for turning on and off the power converting device and temperature dependency of a delay time for conducting and interrupting a current. Hence, MOSFET and other MOS control power converting devices also have the same temperature dependency, and can detect a temperature change by determining a delay time.

As is clear from a signal waveform in FIG. 2, Example 1 employs a configuration where, when the delay time td increases compared to a defined value or more corresponding to a given fixed temperature rise, abnormality determination is outputted. Consequently, it is possible to detect that the temperature of the power semiconductor becomes the defined value or more and take a measure for preventing damages on the power converting device according to an output of this determination. FIG. 3 illustrates a power converting device according to another embodiment of the present invention, and illustrates a configuration where a drive instruction and a drive voltage are changed to prevent damages on the power converting device based on an abnormality determination result. A specific measure for preventing damages on the power converting device according to the example is configured to include turning off power the power semiconductor whose temperature rise has been detected for a certain period of time, turning off another power converting device related to a temperature rise of a power conversion semiconductor whose temperature rise has been detected in a power converting device for a certain period of time, or changing a drive instruction for a certain period of time and outputting a drive instruction to prevent heat generation of a power conversion semiconductor whose temperature rise has been detected. Further, the specific measure may be configured to include outputting a control voltage for forcibly turning off a power semiconductor irrespectively of a drive instruction, based on a determination output of a detected temperature rise to take a measure for an abnormality at a high speed.

Furthermore, a configuration where a drive instruction is changed for a certain period of time and is outputted to prevent heat generation of a power conversion semiconductor whose temperature rise has been detected includes decreasing heat generation of the power conversion semiconductor by limiting and lowering an upper limit value of a current flowing in the power semiconductor for a certain period of time from a point of time at which the temperature rise has been detected, setting or decreasing an upper limit of a time width of a conduction instruction for turning on the power semiconductor, decreasing a period in which a current flows and a temperature rises, and increasing a period in which the power semiconductor is turned off and the temperature lowers, or decreasing a control cycle, decreasing the number of times of switching and decreasing switching loss caused by conduction and interruption.

In this regard, FIG. 2 illustrates the configuration example where, when the delay time td increases to the defined value or more, abnormality determination is outputted. However, there is a case, too, where a delay time decreases during a temperature rise depending on operation conditions such as a difference in element characteristics and an output current. In this case, when the delay time td decreases, a defined value may be set to make abnormality determination.

### Example 2

FIG. 3 illustrates a block configuration of a power converting device according to example 2 which is another embodiment of the present invention, and FIG. 4 illustrates a signal waveform of the power converting device. This example differs from Example 1 in a method for determining an abnormality yet the other points are the same as those of Example 1. This example employs a configuration where a delay time Δtd measured in advance by the power converting device is recorded, and is compared with a minimum value Δtdm and a maximum value Δtdp of an delay time change allowable range calculated and set based on a value of the delay time Δtd during an operation, and, when the delay time Δtd deviates from this range, abnormality determination is outputted. Consequently, it is possible to detect that the temperature of the power semiconductor becomes the defined value or more and take a measure for preventing damages on the power converting device according to an output of this determination. The same method described above can be adopted for a measure for presenting damages.

### Example 3

FIG. 5 illustrates a block configuration of a power converting device according to example 3 which is still another embodiment of the present invention, illustrates a two-level power converting device of three phases which is connected to a power supply 15 and includes a three-phase electric motor 14 as a load, and illustrates details of a configuration of recording a drive condition for determining a delay time and a determination result, and changing a drive instruction based on based on a determination result. The figure illustrates details of a circuit which controls a U phase lower arm, and a U phase upper arm and other V phase and W phase also employ the same configuration. An IGBT which is a power semiconductor 11 of the U phase lower arm relays a drive instruction from a drive instruction arithmetic operation circuit 3 of a logic unit 25 via communication means 18 of a communication unit 23, and is driven by a drive voltage applied between gate and emitter terminals of the IGBT which is an output of a drive circuit 2. A voltage determination circuit 20 compares this drive voltage and a defined value to determine whether this drive voltage is higher or lower than the defined value, and transmits a comparison and determination result to the logic unit 25 via the communication means 19. A delay calculation circuit calculates a delay time of the drive instruction and this transmitted determination result, and inputs the delay time to a recording determination circuit 6. The recording determination circuit 6 records a delay time at a set timing and under a drive condition. In this case, the drive condition applies when at least one or more drive conditions including a drive instruction condition such as a current instruction value from a drive instruction arithmetic operation circuit, a temperature, a current value and a current flowing direction determined based on signals from a temperature sensor 16, a current sensor 17 and a voltage sensor 18 installed near the IGBT, and a voltage applied to the power semiconductors match with set drive conditions. In this regard, the voltage sensor monitors a voltage applied to the power semiconductors, yet may monitor the voltage of the power supply 15. Further, the set timing is desirably a time at which the power converting device starts operating or a time at which maintenance is finished, i.e., a time at which temporal deterioration of the power converting device can be ignored.

The delay time recorded in this way and a subsequent delay time under a defined drive condition during an operation of the power converting device are compared on a regular basis and, when a delay time change amount exceeds a set value or the number of times that the delay time change amount exceeds the set value exceeds a fixed frequency, an abnormality is determined. Further, the delay time is recorded at a fixed timing or a point of time at which an abnormality is determined, and, when the delay time change amount exceeds a fixed change amount during this recording time, an abnormality can be determined, too. In this regard, a drive condition for recording or determining a delay time defined herein does not need to be one condition and, by increasing the number of conditions, it is possible to further enhance temperature rise determination precision.

The external output circuit 8 is configured to output the delay time recorded by the recording determination circuit 6 and a drive condition in this case together, and an external PC can perform numerical analysis and history survey, and evaluate whether or not there is an abnormality and a remaining operational life in detail. Further, the instruction arithmetic operation circuit 7 changes a drive instruction according to an abnormality determination result, so that it is possible to reduce heat generation of the power semiconductor. Even when the power semiconductor deteriorates, it is possible to enable long-term use by reducing an output of the power semiconductor by the above-described method.

### Example 4

FIG. 6 illustrates a block configuration of a power converting device according to example 4 which is still another embodiment of the present invention, and illustrates a configuration where a function of the present invention is additionally provided to an existing power converting device in particular. In this example, a signal split circuit 31 is provided between a communication unit 23 and a sensor unit 33 connected with a logic unit 25, and an additional-type determination circuit 36 determines an abnormality. The signal split circuit includes an optical or electrical signal split circuit, and an output buffer circuit 32 which transmits a result of the optical or electrical signal split circuit to the additional-type determination circuit 36. A level determination circuit 34 stabilizes a numerical value of this output, and a delay time calculation abnormality determination circuit 35 receives an input of a delay time and a drive condition and outputs a determination result based on the delay time and the drive condition to an external output circuit 8 or the logic unit 25. By employing such a configuration, it is possible to add to existing products a function of detecting a temperature abnormality and evaluating a remaining operational life. Further, when the power converting device is inspected on a regular basis, it is possible to check soundness of the power converting device by temporarily inserting and operating the signal split circuit 31 and the additional-type determination circuit 36 and evaluating a delay time.

As described above, according each of the examples of the present invention, it is possible to provide a power converting device which can precisely detect an abnormality and deterioration of a power semiconductor and the power converting device related to the power semiconductor by detecting a temperature based on a delay time of a drive instruction to the power semiconductor and a drive voltage and precisely prevent a trouble such as a failure while employing a simple configuration, and enable long-time use.

In addition, a method for diagnosing and protecting an abnormality and deterioration by detecting a temperature rise of a power semiconductor according to the present embodiment has been described above. However, it is possible to diagnose and protect deterioration and an abnormality of each unit of a power converting device which causes the same temperature abnormality by the same method, too.

### REFERENCE SIGNS LIST

1 power semiconductor
2 drive circuit
3 drive instruction arithmetic operation circuit
4 delay calculation circuit
5 abnormality determination circuit
6 recording determination circuit
7 instruction arithmetic operation circuit
8 external output circuit
9 load
11, 12 IGBT
13 current sensor
14 electric motor
15 power supply
16 temperature sensor
17 voltage sensor
18, 19 communication means
20 voltage determination circuit
21, 22 driving unit
23, 24 communication unit
25 logic unit
31 signal split circuit
32 output buffer circuit
33 sensor unit
34 level determination circuit
35 delay calculation/abnormality determination circuit
36 additional-type determination circuit

1. A power converting device comprising:
a power semiconductor; and
an arithmetic operation circuit which gives a drive instruction to the power semiconductor, wherein
the power converting device has a function of calculating for a drive instruction to conduct or interrupt the power semiconductor a delay time taken until an output voltage of a drive circuit applied to the power semiconductor in response to a change in the drive instruction reaches a determination value, and
compares and determines the delay time and a reference value under a specific drive condition, records or displays and outputs a result of the determination, or changes at least one of the drive instruction and the drive voltage based on a result of the comparison and the determination.

2. The power converting device according to claim 1, wherein the power semiconductor includes an insulation gate bipolar transistor, a power MOSFET or a MOS gate control power semiconductor element.

3. The power converting device according to claim 1, wherein the specific drive condition for making comparison with and determination on the reference value is one of an output current value of the power converting device, a direction of an output current flowing the power semiconductor, an inter-output terminal voltage of the power semiconductor, a power voltage and a temperature in the power converting device or a combination of the output current value, the direction, the inter-output terminal voltage, the power voltage and the temperature.

4. The power converting device according to claim 1, wherein the delay time measured in advance by the power converting device is recorded, and a value calculated by performing an arithmetic operation on a value of the delay time is used for the reference value to make comparison with and determination on the delay time.

5. The power converting device according to claim 1, wherein, when a result obtained by the comparison and the determination is recorded, and a number of times of the recording or a time interval of the recording satisfies a given condition, a display output or at least one of the drive instruction and the drive voltage is changed.

6. The power converting device according to claim 1, wherein the drive instruction or the drive voltage is changed to interrupt the power semiconductor for a certain period of time based on the result of the comparison and the determination.

7. The power converting device according to claim 1, wherein an upper limit value of a current flowing to the power semiconductor is decreased, a time width of a conduction instruction of the power semiconductor according to the drive instruction is decreased or a frequency to control the conduction and the interruption is decreased based on the result of the comparison and the determination.

8. The power converting device according to claim 1, further comprising means which communicates a signal of the drive instruction, and a signal of a result indicating that the output voltage of the drive circuit has reached the determination value between the arithmetic operation circuit and the power semiconductor; and
a determination circuit which receives an input of the signal of the communication means and a signal related to the specific drive condition, and compares and determines the delay times and the reference value,
wherein a result of the determination is outputted to the arithmetic operation circuit or the drive circuit.

9. The power converting device according to claim 1, further comprising communication means which records the result of the determination and outputs a result of the recording to an outside.
